(19) United States
(12) Patent Application Publication
(10) Pub. No.: US 2019/0278176 A1
(43) Pub. Date: Sep. 12, 2019

(54) PHOTOSENSITIVE RESIN COMPOSITION, PHOTOSENSITIVE RESIN LAYER USING THE SAME AND ELECTRONIC DEVICE

(71) Applicant: SAMSUNG SDI CO., LTD., Yongin-si (KR)

(72) Inventors: Taek-Jin BAEK, Suwon-si (KR); Jinhee KANG, Suwon-si (KR); Heekyoung KANG, Suwon-si (KR); Sang Soo KIM, Suwon-si (KR); Ji Yoon KIM, Suwon-si (KR); Chiwon AN, Suwon-si (KR); Bumjin LEE, Suwon-si (KR); Chungbeum HONG, Suwon-si (KR)

(21) Appl. No.: 16/294,218

(22) Filed: Mar. 6, 2019

(30) Foreign Application Priority Data
Mar. 9, 2018 (KR) 10-2018-0027899

(51) Int. Cl. G03F 7/022; G03F 7/038

(52) U.S. Cl. CPC G03F 7/0226; G03F 7/0387

(57) ABSTRACT

A photosensitive resin composition includes an alkali soluble resin, a photosensitive diazoquinone compound, a compound represented by Chemical Formula 1, and a solvent,

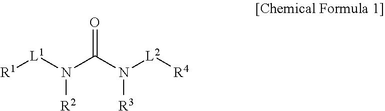

wherein, in Chemical Formula 1, each substituent is the same as defined in the specification.

### CROSS-REFERENCE TO RELATED APPLICATION

Korean Patent Application No. 10-2018-0027899, filed on Mar. 9, 2018, in the Korean Intellectual Property Office, and entitled: “Photosensitive Resin Composition, Photosensitive Resin Layer Using the Same and Electronic Device,” is incorporated by reference herein in its entirety.

### BACKGROUND

### 1. Field

Embodiments relate to a photosensitive resin composition, a photosensitive resin layer using the same, and an electronic device including the photosensitive resin layer.

### 2. Description of the Related Art

A polyimide resin, a polybenzoxazole resin, and the like having improved heat resistance, electrical characteristics, and mechanical characteristics, have been widely used for a surface protective layer and an interlayer insulating layer used in materials for display device panels and semiconductor devices.

### SUMMARY

Embodiments are directed to a photosensitive resin composition, including an alkali soluble resin, a photosensitive diazoquinone compound, a compound represented by Chemical Formula 1, and a solvent.

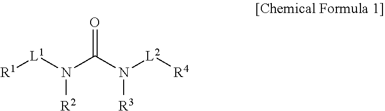

In Chemical Formula 1,

L¹ and L² may independently be a substituted or unsubstituted C1 to C20 alkylene group, and

R¹ to R⁴ may independently be a hydrogen atom, a hydroxy group, a substituted or unsubstituted C1 to C20 alkyl group, or a substituted or unsubstituted C1 to C20 alkoxy group, and R¹ to R⁴ may be independently present or may be linked with each other to form a ring.

The compound represented by Chemical Formula 1 may be represented by Chemical Formula 1-1 or Chemical Formula 1-2.

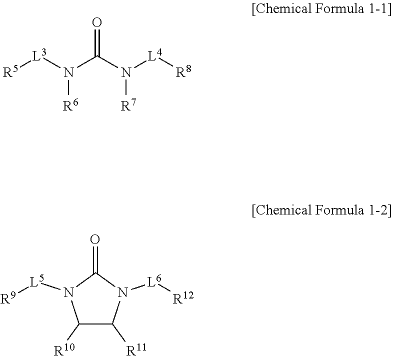

In Chemical Formula 1-1 and Chemical Formula 1-2,

L³ to L⁶ may independently be a substituted or unsubstituted C1 to C20 alkylene group,

R⁵, R⁸, R⁹, and R¹² may independently be a substituted or unsubstituted C1 to C20 alkoxy group,

R⁶ and R⁷ may independently be a hydrogen atom or a substituted or unsubstituted C1 to C20 alkyl group, and

R¹⁰ and R¹¹ may independently be a substituted or unsubstituted C2 to C20 alkoxy group.

R⁶ and R⁷ may independently be a substituted or unsubstituted C1 to C20 alkyl group.

R⁹ to R¹² may independently be a C1 to C20 alkoxy group substituted with a C1 to C10 alkyl group.

The compound represented by Chemical Formula 1 may be represented by one of Chemical Formula 1-1-1 to Chemical Formula 1-1-4 and Chemical Formula 1-2-1 to Chemical Formula 1-2-4.

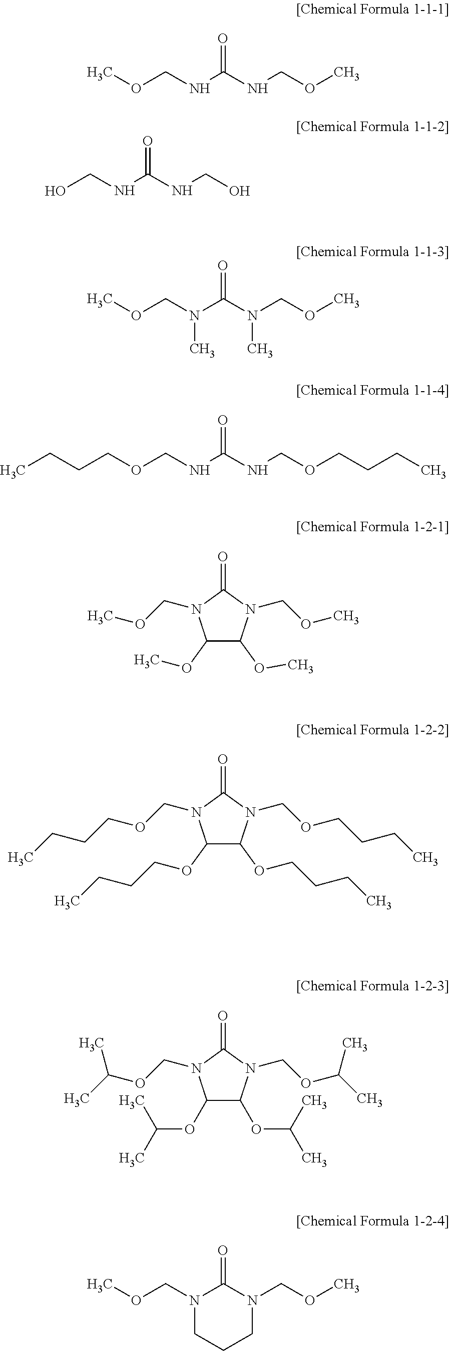

The photosensitive resin composition may include about 1 part by weight to about 100 parts by weight of the photosensitive diazoquinone compound, about 1 part by weight to about 30 parts by weight of the compound represented by Chemical Formula 1, and about 100 parts by weight to about 500 parts by weight of the solvent based on 100 parts by weight of the alkali soluble resin.

The photosensitive resin composition may malonic acid, 3-amino-1,2-propanediol, a leveling agent, a surfactant, a radical polymerization initiator, or a combination thereof.

Embodiments are also directed to a photosensitive resin layer manufactured using the photosensitive resin composition.

Embodiments are also directed to an electronic device including the photosensitive resin layer.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen atom by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” refers to inclusion of at least one heteroatom of N, O, S, and P, in chemical formula.

As used herein, when specific definition is not otherwise provided, “(meth)acrylate” refers to both “acrylate” and “methacrylate”, and “(meth)acrylic acid” refers to “acrylic acid” and “methacrylic acid”.

As used herein, when a definition is not otherwise provided, “combination” refers to mixing or copolymerization. In addition, “copolymerization” refers to block copolymerization to random copolymerization and “copolymer” refers to a block copolymer to a random copolymer.

As used herein, when specific definition is not otherwise provided, an unsaturated bond includes a bond between other atoms such as a carbonyl bond, or an azo bond as well as a multi-bond between carbon-carbon atoms.

As used herein, when a definition is not otherwise provided, hydrogen is bonded at the position when a chemical bond is not drawn in chemical formula where supposed to be given.

In addition, as used herein, when a definition is not otherwise provided, “*” refers to a linking point with the same or different atom or chemical formula.

A photosensitive resin composition according to an embodiment includes (A) an alkali soluble resin; (B) a photosensitive diazoquinone compound; (C) a compound represented by Chemical Formula 1; and (D) a solvent.

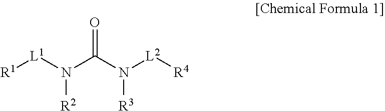

In Chemical Formula 1,

L¹ and L² may independently be a substituted or unsubstituted C1 to C20 alkylene group, and

R¹ to R⁴ may independently be a hydrogen atom, a hydroxy group, a substituted or unsubstituted C1 to C20 alkyl group, or a substituted or unsubstituted C1 to C20 alkoxy group. Additionally, R¹ to R⁴ may be independently present or linked with each other to form a ring, e.g., two adjacent ones of R¹ to R⁴ may be linked together to form a ring.

When the photosensitive resin composition according to an embodiment is used as a protective film or an insulating layer in a semiconductor or a display device, the composition may be applied by coating it, UV exposure, development, and curing.

Hereinafter, each component is specifically described.

(C) Compound Represented by Chemical Formula 1

The compound represented by Chemical Formula 1 may act as a cross-linking agent. The cross-linking agent may provide a stable structure, and may improve adhesion force with the substrate while securing an excellent elongation characteristics.

According to an example embodiment, the compound represented by Chemical Formula 1 includes at least two nitrogen atoms. Thus, alkali solubility of the film may be improved. Additionally, a cured relief pattern having an improved pattern profile, a high glass transition temperature, and a close-contacting property with a substrate may be provided.

Without being bound by theory, it is believed that alkali solubility of the film may be enhanced by the polar group having a nitrogen atom, which may have a good affinity with an alkali solution. Further, it is believed that good relief pattern profile results after curing are related to the compound having a polar group having a nitrogen atom that forms a rigid hydrogen bond with a hydroxyl group of an alkali soluble resin. Thus a softening point of the alkali-soluble resin may be increased and a pattern may be prevented from being softened during a temperature increase during a curing process. Further, it is believed that a high glass transition temperature of the cured relief pattern may be provided by the rigid hydrogen bond formation. Further, it is believed that the cured relief pattern has a close contact property with the substrate due to the polar group with the nitrogen atom interacting strongly with the substrate.

According to an example embodiment, the compound represented by Chemical Formula 1 may have a non-cyclic structure or cyclic structure, for example, respectively represented by Chemical Formula 1-1 or Chemical Formula 1-2:

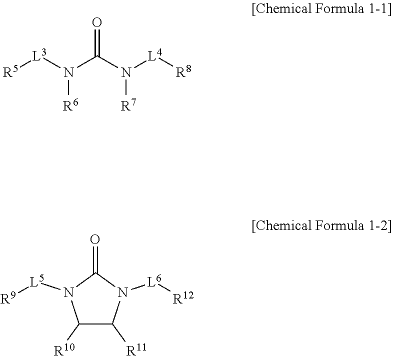

In Chemical Formula 1-1 and Chemical Formula 1-2,

L³ to L⁶ may independently be a substituted or unsubstituted C1 to C20 alkylene group,

R⁵, R⁸, R⁹, and R¹² may independently be a substituted or unsubstituted C1 to C20 alkoxy group,

R⁶ and R⁷ may independently be a hydrogen atom or a substituted or unsubstituted C1 to C20 alkyl group, and

R¹⁰ and R¹¹ may independently be a substituted or unsubstituted C2 to C20 alkoxy group.

For example, R⁶ and R⁷ may independently be a substituted or unsubstituted C1 to C20 alkyl group.

For example, R⁹ to R¹² may independently be a C1 to C20 alkoxy group substituted with a C1 to C10 alkyl group.

In an example embodiment, the compound represented by Chemical Formula 1 may be represented by one of Chemical Formula 1-1-1 to Chemical Formula 1-1-4 and Chemical Formula 1-2-1 to Chemical Formula 1-2-4:

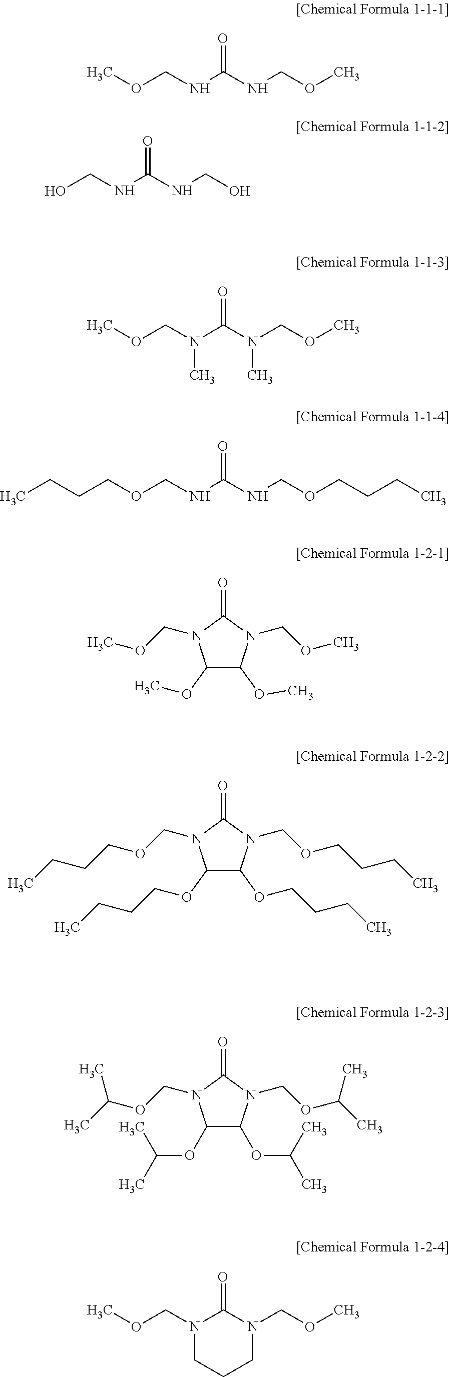

In an example embodiment, the compound represented by Chemical Formula 1 may be represented by one of Chemical Formula 1-1-1, Chemical Formula 1-1-3, Chemical Formula 1-1-4, Chemical Formula 2-1-2, or Chemical Formula 2-1-3.

In an example embodiment, the compound represented by Chemical Formula 1 may be included in an amount of about 1 part by weight to about 30 parts by weight, for example about 5 parts by weight to about 20 parts by weight, based on about 100 parts by weight of the alkali soluble resin. When the compound represented by Chemical Formula 1 is included in the stated ranges, elongation and adhesion force may be improved.

(A) Alkali Soluble Resin

The alkali soluble resin may be or may include, for example, a polyhydroxyamide resin, a polyimide precursor, a novolac resin, a bisphenol A resin, a bisphenol F resin, an acrylate resin, or a combination thereof.

In an example embodiment, the polyhydroxyamide resin may include a structural unit represented by Chemical Formula 2. In an example embodiment, the polyimide precursor may include a structural unit represented by Chemical Formula 3.

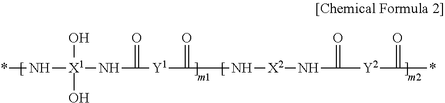

In Chemical Formula 2,

X¹ and X² may independently be a substituted or unsubstituted C6 to C30 aromatic organic group,

Y¹ and Y² may independently be a substituted or unsubstituted C6 to C30 aromatic organic group, a substituted or unsubstituted divalent C1 to C30 aliphatic organic group, or a substituted or unsubstituted divalent C3 to C30 alicyclic organic group,

m1 may be an integer ranging from 2 to 1000, m2 may be an integer ranging from 0 to 500, and m1/(m1+m2)>0.5.

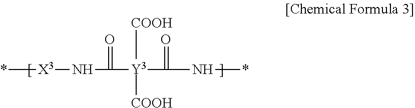

In Chemical Formula 3,

X³ may be a substituted or unsubstituted C6 to C30 aromatic organic group, a substituted or unsubstituted divalent C1 to C30 aliphatic organic group, or a substituted or unsubstituted divalent C3 to C30 alicyclic organic group, and

Y¹ may be a substituted or unsubstituted C6 to C30 aromatic organic group, a substituted or unsubstituted quadrivalent C1 to C30 aliphatic organic group, or a substituted or unsubstituted quadrivalent C3 to C30 alicyclic organic group.

In Chemical Formula 2, X¹ may be a moiety derived from aromatic diamine as an aromatic organic group. Examples of the aromatic diamine include 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, 2,2-bis(3-amino-4-hydroxyphenyl)-1,1,1,3,3,3-hexafluoropropane, 2,2-bis(4-amino-3-hydroxyphenyl)-1,1,1,3,3,3-hexafluoropropane, 2,2-bis(3-amino-4-hydroxy-5-trifluoromethylphenyl)hexafluoropropane, 2,2-bis(3-amino-4-hydroxy-6-trifluoromethylphenyl)hexafluoropropane, 2,2-bis(3-amino-4-hydroxy-2-trifluoromethylphenyl)hexafluoropropane, 2,2-bis(4-amino-3-hydroxy-5-trifluoromethylphenyl)hexafluoropropane, 2,2-bis(4-amino-3-hydroxy-6-trifluoromethylphenyl)hexafluoropropane, 2,2-bis(4-amino-3-hydroxy-2-trifluoromethylphenyl)hexafluoropropane, 2,2-bis(3-amino-4-hydroxy-5-pentafluoroethylphenyl)hexafluoropropane, 2-(3-amino-4-hydroxy-5-trifluoromethylphenyl)-2-(3-amino-4-hydroxy-5-pentafluoroethylphenyl)hexafluoropropane, 2-(3-amino-4-hydroxy-5-trifluoromethylphenyl)-2-(3-hydroxy-4-amino-5-trifluoromethylphenyl)hexafluoropropane, 2-(3-amino-4-hydroxy-5-trifluoromethylphenyl)-2-(3-hydroxy-4-amino-6-trifluoromethylphenyl)hexafluoropropane, 2-(3-amino-4-hydroxy-5-trifluoromethylphenyl)-2-(3-hydroxy-4-amino-2-trifluoromethylphenyl)hexafluoropropane, 2-(3-amino-4-hydroxy-2-trifluoromethylphenyl)-2-(3-hydroxy-4-amino-5-trifluoromethylphenyl)hexafluoropropane, and 2-(3-amino-4-hydroxy-6-trifluoromethylphenyl)-2-(3-hydroxy-4-amino-5-trifluoromethylphenyl)hexafluoropropane, etc.

Examples of X¹ includes a functional group represented by Chemical Formula 4 and Chemical Formula 5:

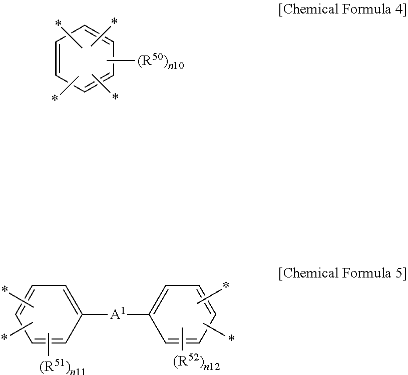

Examples of X² includes a functional group represented by Chemical Formula 4-1 and Chemical Formula 5-1:

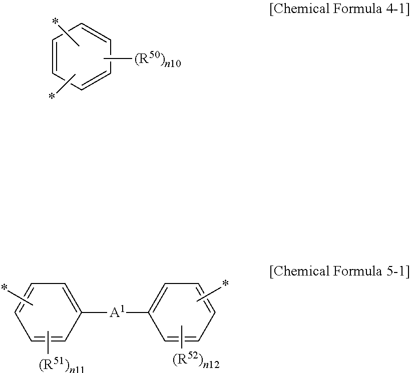

In Chemical Formula 4, Chemical Formula 4-1, Chemical Formula 5, and Chemical Formula 5-1,

A¹ may be a single bond, O, CO, CR⁴⁷R⁴⁸, SO₂, or S, and R⁴⁷ and R⁴⁸ may independently be a hydrogen atom or a substituted or unsubstituted C1 to C30 alkyl group, for example, a C1 to C30 fluoroalkyl group,

R⁵⁰ to R⁵² may independently be a hydrogen atom, a substituted or unsubstituted C1 to C30 alkyl group, a substituted or unsubstituted C1 to C30 carboxyl group, a hydroxy group, or a thiol group,

n10 may be an integer ranging from 0 to 2, and n1 and n12 may independently be an integer ranging from 0 to 3.

In Chemical Formula 2, Y¹ and Y² may independently be a moiety of dicarboxylic acid or a moiety of a dicarboxylic acid derivative as an aromatic organic group, a divalent to hexavalent aliphatic organic group, or a divalent to hexavalent alicyclic organic group. For example, Y¹ and Y² may independently be an aromatic organic group or a divalent to hexavalent alicyclic organic group.

Specific examples of the dicarboxylic acid derivative include 4,4′-oxydibenzoyl chloride, diphenyloxydicarbonyl dichloride, bis(phenylcarbonyl chloride)sulfone, bis(phenylcarbonylchloride)ether, bis(phenylcarbonyl chloride)phenone, phthaloyl dichloride, terephthaloyl dichloride, isophthaloyl dichloride, dicarbonyl dichloride, diphenyloxy dicarboxylate dibenzotriazole, a combination thereof, etc.

Examples of Y¹ and Y² include functional groups represented by Chemical Formula 6 to Chemical Formula 8.

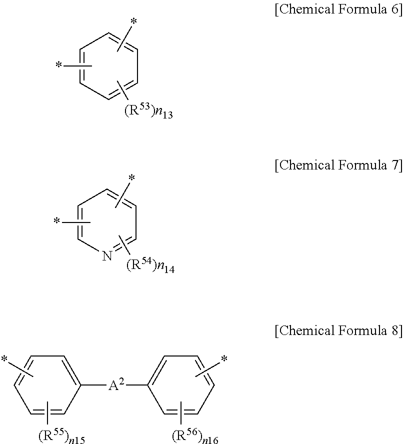

In Chemical Formula 6 to Chemical Formula 8,

R⁵³ to R⁵⁶ may independently be a hydrogen atom, or a substituted or unsubstituted C1 to C30 alkyl group,

n13 and n14 may independently be an integer ranging from 0 to 4, and n15 and n16 may independently be an integer ranging from 0 to 3, and

A² may be a single bond, O, CR⁴⁷R⁴⁸, CO, CONH, S, or SO₂, and R⁴⁷ and R⁴⁸ may independently be a hydrogen atom or a substituted or unsubstituted C1 to C30 alkyl group, for example, a C1 to C30 fluoroalkyl group.

In Chemical Formula 3, X³ may be an aromatic organic group, a divalent to hexavalent aliphatic organic group, or a divalent to hexavalent alicyclic organic group. For example, X³ may be an aromatic organic group or a divalent to hexavalent alicyclic organic group.

For example, X³ may be a moiety derived from aromatic diamine, alicyclic diamine, or silicon diamine. Herein, the aromatic diamine, the alicyclic diamine, and the silicon diamine may be used alone, or in a mixture or combination of one or more.

Examples of the aromatic diamine include 3,4′-diaminodiphenylether, 4,4′-diaminodiphenylether, 3,4′-diaminodiphenylmethane, 4,4′-diaminodiphenylmethane, 4,4′-diaminodiphenylsulfone, 4,4′-diaminodiphenylsulfide, benzidine, m-phenylenediamine, p-phenylenediamine, 1,5-naphthalenediamine, 2,6-naphthalenediamine, bis[4-(4-aminophenoxy)phenyl]sulfone, bis(3-aminophenoxyphenyl)sulfone, bis(4-aminophenoxy)biphenyl, bis[4-(4-aminophenoxy)phenyl]ether, 1,4-bis(4-aminophenoxy)benzene, a compound including an aromatic ring substituted with an alkyl group or a halogen atom, a combination thereof, etc.

Examples of the alicyclic diamine include 1,2-cyclohexyl diamine, 1,3-cyclohexyl diamine, a combination thereof, etc.

Examples of the silicon diamine include bis(4-aminophenyl)dimethylsilane, bis(4-aminophenyl)tetramethylsiloxane, bis(p-aminophenyl)tetramethyldisiloxane, bis(γ-aminopropyl)tetramethyldisiloxane, 1,4-bis(γ-aminopropyldimethylsilyl)benzene, bis(4-aminobutyl)tetramethyldisiloxane, bis(γ-aminopropyl)tetraphenyldisiloxane, 1,3-bis(aminopropyl)tetramethyldisiloxane, a combination thereof, etc.

In Chemical Formula 3, Y³ may be an aromatic organic group, a quadrivalent to hexavalent aliphatic organic group, or a quadrivalent to hexavalent alicyclic organic group. For example, Y³ may be an aromatic organic group or a quadrivalent to hexavalent alicyclic organic group.

Y³ may be a moiety derived from aromatic acid dianhydride or alicyclic acid dianhydride. Herein, the aromatic acid dianhydride and the alicyclic acid dianhydride may be used alone, or in a mixture or combination of one or more.

Examples of the aromatic acid dianhydride include pyromellitic dianhydride; benzophenone tetracarboxylic dianhydride such as benzophenone-3,3′,4,4′-tetracarboxylic dianhydride; oxydiphthalic dianhydride such as 4,4′-oxydiphthalic dianhydride; biphthalic dianhydride such as 3,3′,4,4′-biphthalic dianhydride; (hexafluoroisopropylidene)diphthalic dianhydride such as 4,4′-(hexafluoroisopropylidene)diphthalic dianhydride; naphthalene-1,4,5,8-tetracarboxylic dianhydride; 3,4,9,10-perylenetetracarboxylic dianhydride, etc.

Examples of the alicyclic acid dianhydride include 1,2,3,4-cyclobutanetetracarboxylic dianhydride, 1,2,3,4-cyclopentanetetracarboxylic dianhydride, 5-(2,5-dioxotetrahydrofuryl)-3-methyl-cyclohexane-1,2-dicarboxylic anhydride), 4-(2,5-dioxotetrahydrofuran-3-yl)-tetralin-1,2-dicarboxylic anhydride, bicyclooctene-2,3,5,6-tetracarboxylic dianhydride, bicyclooctene-1,2,4,5-tetracarboxylic dianhydride, etc.

The alkali soluble resin may have a weight average molecular weight (Mw) of about 3,000 g/mol to about 300,000 g/mol, for example, about 5,000 g/mol to about 30,000 g/mol. When the weight average molecular weight (Mw) is within the range, a desired film residue ratio may be obtained in a non-exposed region during the development with an alkali aqueous solution, and patterning may be efficiently conducted.

(B) Photosensitive Diazoquinone Compound

The photosensitive diazoquinone compound may be, for example, a compound having a 1,2-benzoquinonediazide structure or a 1,2-naphthoquinone diazide structure.

Examples of the photosensitive diazoquinone compound include compounds represented by Chemical Formula 9 and Chemical Formula 11 to Chemical Formula 13.

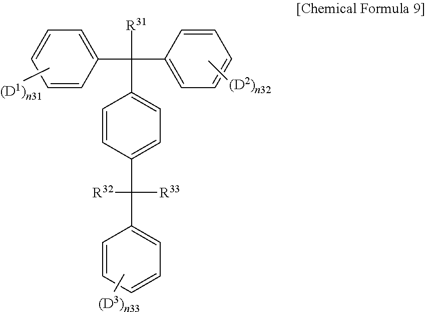

In Chemical Formula 9,

R³¹ to R³³ may independently be a hydrogen atom or a substituted or unsubstituted alkyl group, for example, CH₃,

D₁ to D₃ may independently be OQ, wherein the Q may be hydrogen atom or a functional group represented by Chemical Formula 10a or 10b,

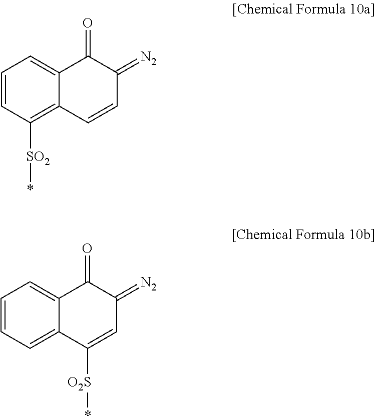

and

n31 to n33 are independently integers of 1 to 5.

In an example embodiment, the Q's are not simultaneously a hydrogen atom.

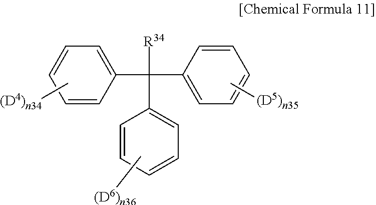

In Chemical Formula 11,

R³⁴ may be a hydrogen atom or a substituted or unsubstituted alkyl group,

D⁴ to D⁶ may independently be OQ, wherein Q is the same as defined in Chemical Formula 9, and

n34 to n36 may independently be integers of 1 to 5.

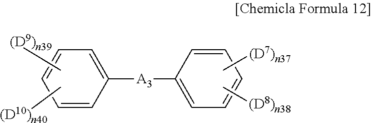

In Chemical Formula 12,

A₃ may be CO or CR⁵⁰⁰R⁵⁰¹, wherein R⁵⁰⁰ and R⁵⁰¹ may independently be a substituted or unsubstituted alkyl group,

D⁷ to D¹⁰ may independently be a hydrogen atom, a substituted or unsubstituted alkyl group, OQ, or NHQ, wherein Q is the same as defined in Chemical Formula 9,

n37, n38, n39, and n40 may independently be integers of 1 to 4, and

the sum of n37+n38 and the sum of n39+n40 may independently be integers of less than or equal to 5.

In an example embodiment of Chemical Formula 12, at least one of the D⁷ to D¹⁰ is OQ. In an example embodiment, one phenyl ring includes one to three OQ's and the other phenyl ring includes one to four OQ's.

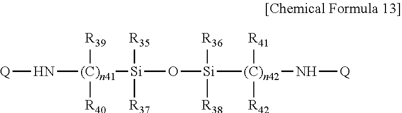

In Chemical Formula 13,

R₃₅ to R₄₂ may independently be a hydrogen atom or a substituted or unsubstituted alkyl group,

n41 and n42 may independently be integers of 1 to 5, for example 2 to 4, and

Q is the same as defined in Chemical Formula 9.

The photosensitive diazoquinone compound may be included in an amount of about 1 part by weight to about 100 parts by weight, for example about 10 parts by weight to about 50 parts by weight, based on 100 parts by weight of the alkali soluble resin. When the photosensitive diazoquinone compound is included within the stated ranges, the pattern may be well-formed without residues by exposure, and a film thickness loss during development may be prevented and thereby a good pattern may be provided.

(D) Solvent

The photosensitive resin composition may include a solvent capable of easily dissolving each component, for example the alkali soluble resin, the photosensitive diazoquinone compound, the compound represented by Chemical Formula 1, and the like.

The solvent may be an organic solvent, for example N-methyl-2-pyrrolidone, gamma-butyrolactone, N,N-dimethyl acetamide, dimethylsulfoxide, diethylene glycoldimethylether, diethylene glycoldiethylether, diethylene glycoldibutylether, propylene glycolmonomethylether, dipropylene glycolmonomethylether, propylene glycolmonomethyl ether acetate, methyl lactate, ethyl lactate, butyl lactate, methyl-1,3-butylene glycolacetate, 1,3-butylene glycol-3-monomethylether, methyl pyruvate, ethyl pyruvate, methyl-3-methoxy propionate, a combination thereof, etc.

The solvent may be selected appropriately depending on a process of forming a photosensitive resin layer such as spin coating, slit die coating, and the like.

The solvent may be used in an amount of about 100 parts by weight to about 500 parts by weight, for example about 100 parts by weight to about 300 parts by weight, based on 100 parts by weight of the alkali soluble resin. When the solvent is used within the stated ranges, a film having a sufficient thickness may be obtained, and solubility and coating properties may be improved.

(E) Other Additives

The photosensitive resin composition according to an example embodiment may include one or more additives.

For example, the photosensitive resin composition may further include additives such as malonic acid, 3-amino-1,2-propanediol, a leveling agent, a coupling agent, a surfactant, a radical polymerization initiator, or a combination thereof, which may help to prevent stains or spots during the coating, to adjust leveling, or to prevent residues due to non-development. Amounts of the additive may be adjusted according to desired properties.

The coupling agent may be, for example, a silane-based coupling agent, and the silane-based coupling agent may have a reactive substituent such as a vinyl group, a carboxyl group, a methacryloxy group, an isocyanate group, an epoxy group, and the like in order to improve close-contacting properties with a substrate.

Examples of the silane-based coupling agent include trimethoxysilylbenzoic acid, γ-methacryloxy propyltrimethoxysilane, vinyltriacetoxysilane, vinyltrimethoxysilane, γ-isocyanate propyltriethoxysilane, γ-glycidoxypropyl trimethoxysilane, β-(3,4-epoxycyclohexyl)ethyl trimethoxysilane, and the like. These may be used singularly or in a mixture of two or more.

The silane-based coupling agent may be used in an amount of about 0.01 parts by weight to about 10 parts by weight based on 100 parts by weight of the photosensitive resin composition. When the silane-based coupling agent is included within the stated ranges, close-contacting properties, storage capability, and the like may be improved.

The surfactant may be added, for example, to help prevent strains of a film or to improve developability, and may include a fluorine-based surfactant and/or a silicone-based surfactant.

Examples of the fluorine-based surfactant include a commercial fluorine-based surfactant such as BM-1000®, and BM-1100® (BM Chemie Inc.); MEGAFACE F 142D®, F 172®, F 173®, F 183 and F 554® (Dainippon Ink Kagaku Kogyo Co., Ltd.); FULORAD FC-135®, FULORAD FC-170C®, FULORAD FC-430®, and FULORAD FC-431® (Sumitomo 3M Co., Ltd.); SURFLON S-112®, SURFLON S-113®, SURFLON S-131®, SURFLON S-141®, and SURFLON S-145 (Asahi Glass Co., Ltd.); and SH-28PA®, SH-190®, SH-193®, SZ-6032®, and SF-8428®, and the like (Toray Silicone Co., Ltd.).

The silicone-based surfactant may be BYK-307, BYK-333, BYK-361N, BYK-051, BYK-052, BYK-053, BYK-067A, BYK-077, BYK-301, BYK-322, BYK-325, and the like, which are made by BYK Chem and commercially available.

The surfactant may be used in an amount of about 0.001 to about 5 parts by weight based on 100 parts by weight of the photosensitive resin composition. When the surfactant is included within the stated range, coating uniformity may be secured, a stain may not be produced, and wetting on an IZO substrate or a glass substrate may be improved.

The photosensitive resin composition may further include an epoxy compound, which may help to improve a close-contacting force, and the like as an additive. The epoxy compound may be an epoxy novolac acryl carboxylate resin, an ortho cresol novolac epoxy resin, a phenol novolac epoxy resin, a tetramethyl biphenyl epoxy resin, a bisphenol A epoxy resin, an alicyclic epoxy resin, a combination thereof, etc.

When the epoxy compound is included, a radical polymerization initiator such as a peroxide initiator or an azobis-based initiator may be further included.

The epoxy compound may be used in an amount of about 0.01 parts by weight to about 5 parts by weight based on 100 parts by weight of the photosensitive resin composition. When the epoxy compound is included within the stated range, storage capability, close-contacting force, and other characteristics may be improved economically.

The photosensitive resin composition may further include a thermal latent acid generator. Examples of the thermal latent acid generator include an arylsulfonic acid such as p-toluene sulfonic acid or benzene sulfonic acid; a perfluoroalkyl sulfonic acid such as trifluoromethane sulfonic acid or trifluorobutane sulfonic acid; an alkylsulfonic acid such as methane sulfonic acid, ethane sulfonic acid, or butane sulfonic acid; or a combination thereof, etc.

The latent thermal acid generator may act as a catalyst for a dehydration reaction and a cyclization reaction of the polybenzoxazole precursor that is polyamide including a phenolic hydroxy group, and thus a cyclization reaction may be performed smoothly even if a curing temperature is decreased.

The photosensitive resin composition according to an example embodiment may include additives such as an antioxidant, a stabilizer, and the like in a suitable amount.

According to an example embodiment, a photosensitive resin layer may be manufactured, for example, by exposure, development, and curing of the photosensitive resin composition.

According to an example embodiment, an electronic device includes the photosensitive resin layer. The electronic device may be a semiconductor device.

A method of manufacturing a photosensitive resin layer according to an example embodiment is described below.

(1) Coating and Layer Formation

The photosensitive resin composition may be coated to have a desired thickness on a substrate such as a glass substrate or an ITO substrate, which may undergo a predetermined pretreatment, using a spin or slit coating method, a roll coating method, a screen-printing method, an applicator method, and the like. Then, the coated substrate may be heated at a temperature ranging from, for example, about 70° C. to about 150° C. for about 1 minute to about 10 minutes, to remove a solvent and to form a layer.

(2) Exposure

The obtained photosensitive resin layer may be radiated by an active ray of, for example, 200 nm to 500 nm after placing a mask with a predetermined shape to form a desired pattern. The radiation may be performed by using a light source such as a mercury lamp with a low pressure, a high pressure, or an ultrahigh pressure, a metal halide lamp, an argon gas laser, and the like. In an implementation, an X ray, an electron beam, and the like may be used.

The exposure dose may be selected depending on a type of each component of the composition, its combination ratio, and a dry film thickness. In an implementation, the exposure dose may be less than or equal to 500 mJ/cm² (according to a 365 nm sensor) when a high pressure mercury lamp is used.

(3) Development

In a developing method, after the exposure operation, the exposed part may be dissolved and removed by using a developing solution to leave only a non-exposed part as obtain a pattern. In an example embodiment, the exposed portions of the photosensitive resin layer may be removed in a positive exposure process.

(4) Post-process Process

An image pattern obtained by development in the above processes may be post-heated, which may help to provide a pattern having improved heat resistance, light resistance, close-contacting properties, crack resistance, chemical resistance, high strength, and storage stability. For example, after development, it may be heated in a convection oven at 250° C. for 1 hour.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

(Synthesis of Alkali Soluble Resin)

12.4 g of 2,2-bis(3-amino-4-hydroxyphenyl)-1,1,1,3,3,3-hexafluoropropane was dissolved in 125 g of N-methyl-2-pyrrolidone (NMP) in a four-necked flask equipped with a stirrer, a temperature controller, a nitrogen gas injector, and a condenser, while nitrogen was passed therethrough.

When a solid was completely dissolved, 4.2 g of pyridine was added thereto, and a solution prepared by dissolving 9.4 g of 4,4′-oxydibenzoylchloride in 100 g of NMP was slowly added in a dropwise fashion to the four-necked flask for 30 minutes, while maintaining temperature at 0° C. to 5° C. When the addition was complete, the obtained mixture was reacted for 1 hour at 0° C. to 5° C., and then heated up to room temperature and reacted for one hour.

Subsequently, 1.1 g of 5-norbornene-2,3-dicarboxyl anhydride was added thereto, and the obtained mixture was stirred at 70° C. for 24 hours, completing a reaction. The reaction mixture was put in a mixed solution of water/methanol=10/1 (a volume ratio) to generate a precipitate, and the precipitate was filtered, sufficiently washed with water, and dried at 80° C. under vacuum for greater than or equal to 24 hours to obtain a polyhydroxyamide resin.

(Preparation of Photosensitive Resin Composition)

### Example 1

100 g of the above-prepared polyhydroxyamide resin was added to and dissolved in 300 g of a γ-butyrolactone (GBL) solvent, 30 g of a photosensitive diazoquinone compound having a structure of Chemical Formula A (MIPHOTO TPA517, Miwon Commercial Co., Ltd) and 15 g of a compound represented by Chemical Formula 1-1-1 (E-2651, SANWA CHEMICAL) were added thereto and dissolved therein under a yellow light, and the obtained solution was stirred until it became a homogeneous solution. Subsequently, the solution was filtered with a 0.20 μm fluorine resin filter to obtain a photosensitive resin composition.

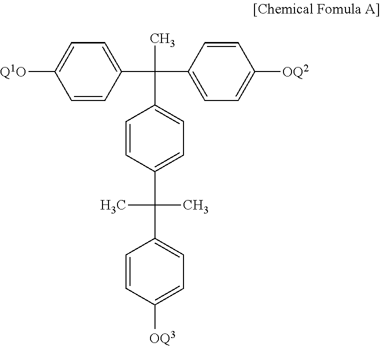

In Chemical Formula A, two of Q¹, Q², and Q³ are the following group

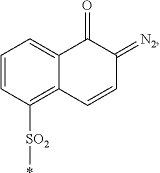

and the remaining one is a hydrogen atom.

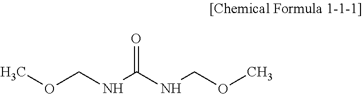

### Example 2

A photosensitive resin composition was prepared according to the same method as Example 1 except that a compound represented by Chemical Formula 1-1-2 (N,N′-bis(hydroxymethyl)urea, Sigma-Aldrich) was used instead of the compound represented by Chemical Formula 1-1-1.

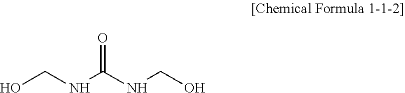

### Example 3

A photosensitive resin composition was prepared according to the same method as Example 1 except that a compound represented by Chemical Formula 1-1-3 (1,3-bis(methoxymethyl)-1,3-dimethylurea, SANWA CHEMICAL) was used instead of the compound represented by Chemical Formula 1-1-1.

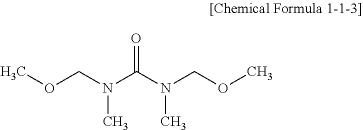

### Example 4

A photosensitive resin composition was prepared according to the same method as Example 1 except that a compound represented by Chemical Formula 1-1-4 (MX-279, SANWA CHEMICAL) was used instead of the compound represented by Chemical Formula 1-1-1.

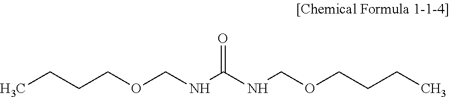 [SMILES: CCCCOCNC(=O)NCOCCCC]

### Example 5

A photosensitive resin composition was prepared according to the same method as Example 1 except that a compound represented by Chemical Formula 1-2-1 (MX-280, SANWA CHEMICAL) was used instead of the compound represented by Chemical Formula 1-1-1.

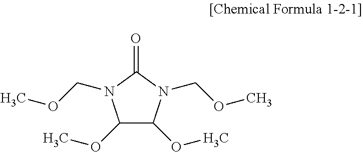

### Example 6

A photosensitive resin composition was prepared according to the same method as Example 1 except that a compound represented by Chemical Formula 1-2-2 (4,5-dibutoxy-1,3-bis(butoxymethyl)imidazolidin-2-one, SANWA CHEMICAL) was used instead of the compound represented by Chemical Formula 1-1-1.

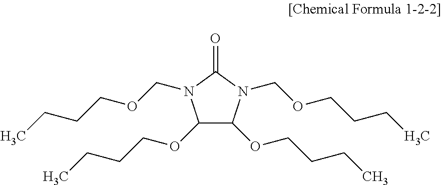 [SMILES: CCCCOCN1C(=O)N(COCCCC)C(OCCCC)C1OCCCC]

### Example 7

A photosensitive resin composition was prepared according to the same method as Example 1 except that a compound represented by Chemical Formula 1-2-3 (4,5-diisopropoxy-1,3-bis(isopropoxymethyl)imidazolidin-2-one, SANWA CHEMICAL) was used instead of the compound represented by Chemical Formula 1-1-1.

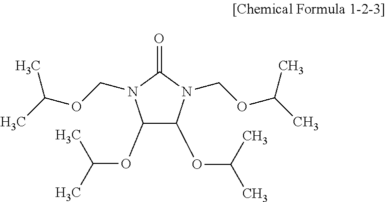 [SMILES: CC(C)OCN1C(=O)N(COC(C)C)C(OC(C)C)C1OC(C)C]

### Example 8

A photosensitive resin composition was prepared according to the same method as Example 1 except that a compound represented by Chemical Formula 1-2-4 (MX-260, SANWA CHEMICAL) was used instead of the compound represented by Chemical Formula 1-1-1.

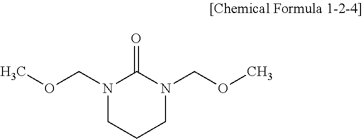

### Comparative Example 1

A photosensitive resin composition was prepared according to the same method as Example 1 except that the compound represented by Chemical Formula 1-1-1 was not used.

Evaluation

The photosensitive resin compositions according to Examples 1 to 8 and Comparative Example 1 were respectively coated on a wafer deposited with aluminum and heated (cured) on a hot plate at 120° C. for 4 minutes to form 10 μm-thick cured films. Resolution, elongation, and adhesion force of the cured films were evaluated, and the results are shown in Table 1.

(Evaluation 1: Resolution)

The resolution was evaluated by obtaining a minimum pattern dimension after the curing.

(Evaluation 2: Elongation)

The cured film was dipped in 10% hydrochloric acid diluted with water (or 1% hydrofluoric acid) for about 20 minutes. Then, the elongation was evaluated by measuring the obtained cured film with a UTM equipment and taking only a maximum value among ten sample measurements.
Grip gap: 50 mm
Cross head speed: 5 mm/min

(Evaluation 3: Adhesion Force)

EMC (an epoxy molding compound) was molded on each cured film. The adhesion force was evaluated by putting each cured film in a chamber at 121° C. under humidity of 100% and measuring a force taken when the EMC was detached from the cured film after 168 hours.

TABLE 1

| | Resolution | Elongation | Adhesion |
|---|---|---|---|
| | (μm) | (%) | force (kgf) |
| Example 1 | 2 | 60 | 25.2 |
| Example 2 | 2 | 60 | 24.7 |
| Example 3 | 2 | 60 | 25.6 |
| Example 4 | 2 | 60 | 24.9 |
| Example 5 | 2 | 55 | 24.8 |
| Example 6 | 2 | 55 | 25.1 |
| Example 7 | 2 | 55 | 25.3 |
| Example 8 | 2 | 55 | 24.8 |
| Comparative | — | 40 | 21.5 |
| Example 1 | | | |

Referring to Table 1, the photosensitive resin composition according to Examples 1-8, which included a compound represented by Chemical Formula 1 as a cross-linking agent, exhibited improved elongation and adhesion force, as well as resolution, as compared with the photosensitive resin composition according to Comparative Example 1, which did not include a compound represented by Chemical Formula 1.

By way of summation and review, a polyimide resin, a polybenzoxazole resin, and the like may be low in solubility in various solvents. They may be provided as a composition in which precursors thereof are dissolved in a solvent.

Recently, reductions in organic solvents have been demanded from the rise of environmental problems, and various types of heat resistant photosensitive resin materials that may be developed with an aqueous alkali solution in the same manner as a photoresist have been proposed.

A method of using a photosensitive resin composition including a mixture of a hydroxypolyamide resin (a polybenzoxazole precursor) soluble in an alkali aqueous solution, which is heat resistant resin after heat curing, and a photoacid generator, such as a naphthoquinone diazide compound, has been considered.

The photosensitive mechanism composition of the photosensitive resin composition is to use exposing the photosensitive diazoquinone compound to a naphthoquinone diazide compound (i.e., a photosensitive diazoquinone compound) and a polybenzoxazole (PBO) precursor in an unexposed portion, and thereby transforming the photosensitive diazoquinone compound into an indenecarboxylic acid compound to increase a dissolution rate in an alkaline aqueous solution. It is possible to manufacture a relief pattern composed of an unexposed portion using a difference in a dissolution rate between an exposed portion and an unexposed portion.

The photosensitive resin composition may form a positive relief pattern by exposure and development with an alkaline aqueous solution. In addition, thermally cured film characteristics may be obtained by heating.

When the cured film is applied to a semiconductor device as a surface protective layer and interlayer insulating layer, high reliability is desired. Although there are many indicators to evaluate reliability, it is important that a tensile elongation of the cured film is increased in order to withstand repeated expansion and expansion of the film depending on a specific temperature. In addition, the cured relief pattern should have a good shape, sufficient alkali solubility, a small amount of residual film at the time of development, and excellent close-contacting properties with the substrate.

As described above, embodiments may provide a photosensitive resin composition having improved resolution, elongation, and adhesion force. Embodiments may also provide a photosensitive resin layer manufactured using the photosensitive resin composition. Embodiments may also provide an electronic device including the photosensitive resin layer.

A photosensitive resin composition according to an embodiment include a specific cross-linking agent, and may improve resolution, elongation, and adhesion force simultaneously.

Reliability, particularly, elongation and adhesion force, are very important in terms of characteristics of process materials. In a photosensitive resin composition according to an embodiment, a compound represented by Formula 1 is included as a cross-linking agent, which may help to improve the elongation and adhesion force while maintaining excellent resolution.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
an alkali soluble resin;
a photosensitive diazoquinone compound;
a compound represented by Chemical Formula 1; and
a solvent, 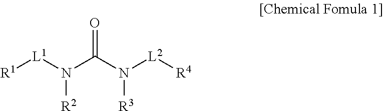
wherein, in Chemical Formula 1,
L¹ and L² are independently a substituted or unsubstituted C1 to C20 alkylene group, and
R¹ to R⁴ are independently a hydrogen atom, a hydroxy group, a substituted or unsubstituted C1 to C20 alkyl group, or a substituted or unsubstituted C1 to C20 alkoxy group, provided that R¹ to R⁴ are independently present or linked with each other to form a ring.

2. The photosensitive resin composition as claimed in claim 1, wherein the compound represented by Chemical Formula 1 is represented by Chemical Formula 1-1 or Chemical Formula 1-2: 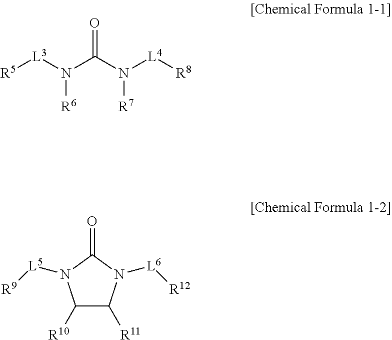
wherein, in Chemical Formula 1-1 and Chemical Formula 1-2,
L³ to L⁶ are independently a substituted or unsubstituted C1 to C20 alkylene group,
R⁵, R⁸, R⁹, and R¹² are independently a substituted or unsubstituted C1 to C20 alkoxy group,
R⁶ and R⁷ are independently a hydrogen atom or a substituted or unsubstituted C1 to C20 alkyl group, and
R¹⁰ and R¹¹ are independently a substituted or unsubstituted C2 to C20 alkoxy group.

3. The photosensitive resin composition as claimed in claim 2, wherein R⁶ and R⁷ are independently a substituted or unsubstituted C1 to C20 alkyl group.

4. The photosensitive resin composition as claimed in claim 2, wherein
R⁹ and R¹² are independently a C1 to C20 alkoxy group substituted with a C1 to C10 alkyl group, and
R¹⁰ and R¹¹ are independently a substituted or unsubstituted C2 to C20 alkoxy group.

5. The photosensitive resin composition as claimed in claim 1, wherein the compound represented by Chemical Formula 1 is represented by one of Chemical Formula 1-1-1, Chemical Formula 1-1-2, Chemical Formula 1-1-3, Chemical Formula 1-1-4, Chemical Formula 1-2-1, Chemical Formula 1-2-2, Chemical Formula 1-2-3, or Chemical Formula 1-2-4:

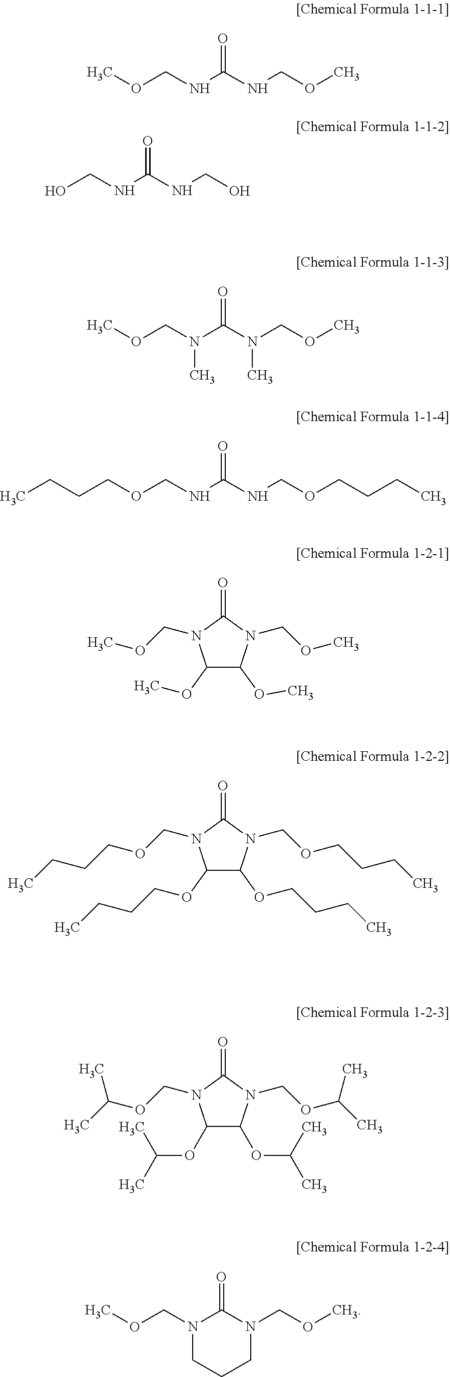

6. The photosensitive resin composition as claimed in claim 1, wherein the photosensitive resin composition comprises:
about 1 part by weight to about 100 parts by weight of the photosensitive diazoquinone compound,
about 1 part by weight to about 30 parts by weight of the compound represented by Chemical Formula 1, and
about 100 parts by weight to about 500 parts by weight of the solvent based on about 100 parts by weight of the alkali soluble resin.

7. The photosensitive resin composition as claimed in claim 1, further comprising malonic acid, 3-amino-1,2-propanediol, a leveling agent, a surfactant, a radical polymerization initiator, or a combination thereof.

8. A photosensitive resin layer manufactured using the photosensitive resin composition as claimed in claim 1.

9. An electronic device comprising the photosensitive resin layer as claimed in claim 8.
